(19) United States
(12) Patent Application Publication
(10) Pub. No.: US 2012/0258555 A1
(43) Pub. Date: Oct. 11, 2012

(54) Multi-Frequency Hollow Cathode and Systems Implementing the Same

(75) Inventors: John Patrick Holland, San Jose, CA (US); Peter L. G. Ventzek, San Francisco, CA (US)

(73) Assignee: Lam Research Corporation, Fremont, CA (US)

(21) Appl. No.: 13/084,325

(22) Filed: Apr. 11, 2011

(51) Int. Cl. H01L 21/66; H01L 21/3065

(52) U.S. Cl. 438/5; 156/345.48; 257/E21.525

(57) ABSTRACT

A hollow cathode system is provided for plasma generation in substrate plasma processing. The system includes an electrically conductive member shaped to circumscribe an interior cavity, and formed to have a process gas inlet in fluid communication with the interior cavity, and formed to have an opening that exposes the interior cavity to a substrate processing region. The system also includes a first radiofrequency (RF) power source in electrical communication with the electrically conductive member so as to enable transmission of a first RF power to the electrically conductive member. The system further includes a second RF power source in electrical communication with the electrically conductive member so as to enable transmission of a second RF power to the electrically conductive member. The first and second RF power sources are independently controllable with regard to frequency and amplitude.

### CROSS-REFERENCE TO RELATED APPLICATIONS

This application is related to U.S. patent application Ser. No. ______ (Attorney Docket No.: LAM2P704B), filed on an even date herewith, and entitled “Multi-Frequency Hollow Cathode System for Substrate Plasma Processing,” which is incorporated herein by reference in its entirety.

### BACKGROUND OF THE INVENTION

Conventional hollow cathodes are required to operate at high pressures on the order of hundreds of milliTorr (mTorr) to atmospheric. Some conventional hollow cathodes operate most effectively at pressures on the order of 1 to 10 Ton, and have interior dimensions sized on the order of millimeters (mm). To be operable, a conventional hollow cathode's interior cavity diameter should be within the range of a few plasma sheath thicknesses. It is this scaling that present a problem for use of conventional hollow cathodes in some semiconductor fabrication processes, such as plasma etch processes, where low pressures are required.

More specifically, conventional hollow cathodes require high radiofrequency (RF) power to generate a plasma at lower gas pressures and have relatively large sizes. Conventional hollow cathodes are not capable of generating high plasma densities with thin plasma sheath thicknesses under simultaneous conditions of low frequency RF power, low pressure, and small hollow cathode dimensions. Therefore, conventional hollow cathodes are not suitable for use in semiconductor fabrication operations where both low pressure and low frequency RF power are simultaneously required, such as in plasma etch operations. It is within this context that the present invention arises.

### SUMMARY OF THE INVENTION

In one embodiment, a hollow cathode system for plasma generation in substrate plasma processing is disclosed. The hollow cathode system includes an electrically conductive member shaped to circumscribe an interior cavity. The electrically conductive member is formed to have a process gas inlet in fluid communication with the interior cavity. The electrically conductive member is also formed to have an opening that exposes the interior cavity to a substrate processing region. The hollow cathode system also includes a first radiofrequency (RF) power source in electrical communication with the electrically conductive member, so as to enable transmission of a first RF power to the electrically conductive member. The hollow cathode system further includes a second RF power source in electrical communication with the electrically conductive member, so as to enable transmission of a second RF power to the electrically conductive member. The first and second RF power sources are independently controllable, such that the first and second RF powers are independently controllable with regard to frequency and amplitude.

In another embodiment, a method is disclosed for substrate plasma processing. The method includes disposing a substrate in exposure to a substrate processing region. The method also includes disposing multiple hollow cathodes in exposure to the substrate processing region. In the method, a process gas is flowed through the multiple hollow cathodes. The method further includes transmitting a plurality of RF powers to the multiple hollow cathodes. The plurality of RF powers are independently controlled with regard to frequency and amplitude, and include at least two different frequencies. At least one of the plurality of RF powers transforms the process gas into a plasma as the process gas flows through the multiple hollow cathodes. Reactive species within the plasma enter the substrate processing region to do work on the substrate.

Other aspects and advantages of the invention will become more apparent from the following detailed description, taken in conjunction with the accompanying drawings, illustrating by way of example the present invention.

### BRIEF DESCRIPTION OF THE DRAWINGS

FIG. 1A shows a vertical cross-section of a hollow cathode assembly, in accordance with one embodiment of the present invention;

FIG. 1B shows a horizontal cross-section of the hollow cathode assembly corresponding to View A-A identified in FIG. 1A, in accordance with one embodiment of the present invention;

FIG. 2A shows a plasma density versus process gas pressure curve for a hollow cathode of a given configuration and dimensions operating at either a single RF frequency or at DC;

FIG. 2B shows a plasma density versus process gas pressure curve for the hollow cathode assembly of FIGS. 1A-1B, in accordance with one embodiment of the present invention;

FIGS. 3A-3B show an electrically conductive member of a hollow cathode system that is formed in multiple parts, in accordance with one embodiment of the present invention;

FIGS. 4A-4B show an electrically conductive member of a hollow cathode system that is Mimed in multiple parts, so as to segment an interior cavity into multiple interior cavities, in accordance with one embodiment of the present invention;

FIG. 5 shows a vertical cross-section through a multi-frequency RF powered hollow cathode, in which an interior cavity of the hollow cathode is shaped to affect process gas pressure, in accordance with one embodiment of the present invention;

FIG. 6A shows the example hollow cathode in which three electrically conductive cathode plates are disposed and separated from each other by dielectric sheets, in accordance with one embodiment of the present invention;

FIG. 6B shows the example hollow cathode, as a variation of the hollow cathode of FIG. 6A, in which the lower ground plate is absent, in accordance with one embodiment of the present invention;

FIG. 6C shows the example hollow cathode, as a variation of the hollow cathode of FIG. 6A, in which three independently controlled RF power sources are used to supply RF power to the cathode plates at three different frequencies, in accordance with one embodiment of the present invention;

FIG. 6D shows the example hollow cathode in which four electrically conductive cathode plates are disposed and separated from each other by dielectric sheets, in accordance with one embodiment of the present invention;

FIG. 6E shows an example hollow cathode in which a single electrically conductive cathode plate is connected to receive multiple RF power frequencies, in accordance with one embodiment of the present invention;

FIG. 7 shows a hollow cathode system for plasma generation in substrate plasma processing, in accordance with one embodiment of the present invention;

FIG. 8 shows a system for substrate plasma processing, in accordance with one embodiment of the present invention;

FIG. 9A shows another system for substrate plasma processing, in accordance with one embodiment of the present invention;

FIG. 9B shows a system for substrate plasma processing that is a variation of the system of FIG. 9A, in accordance with one embodiment of the present invention;

FIG. 10 shows a system for substrate plasma processing that is a variation of the system of FIG. 8, in accordance with one embodiment of the present invention;

FIG. 11 shows a system for substrate plasma processing that is a variation of the system of FIG. 8, in accordance with one embodiment of the present invention; and

FIG. 12 shows a method for substrate plasma processing, in accordance with one embodiment of the present invention.

### DETAILED DESCRIPTION

In the following description, numerous specific details are set forth in order to provide a thorough understanding of the present invention. It will be apparent, however, to one skilled in the art that the present invention may be practiced without some or all of these specific details. In other instances, well known process operations have not been described in detail in order not to unnecessarily obscure the present invention.

A hollow cathode plasma source is operated by creating an electric field in a confined space within the hollow cathode. The electric field excites a process gas supplied to the confined space to transform the process gas into a plasma within the confined space. The plasma is separated by a sheath from the surfaces of the hollow cathode that surround the confined space. In one embodiment, the electric field created within the hollow cathode is referred to as a saddle electric field due to its shape. The electric field within the hollow cathode creates pendulum electrons. The pendulum electrons are born at a surface of the hollow cathode surrounding the confined space, or in the sheath surrounding the plasma. The electrons born at a surface of the hollow cathode or within the sheath are accelerated to an opposing portion of the sheath, whereby the electrons cause ionization of neutral constituents in the process gas, creation of radical species within the process gas, and/or generation of more “fast” electrons.

The electric field within the hollow cathode also confines the plasma within the confined space of the hollow cathode, thereby increasing the plasma density in the confined space. Hollow cathodes provide an attractive means for generating high plasma density, but can have a narrow range of operation with regard to pressure, dimensions, and/or driving voltage. The present invention provides hollow cathodes and associated methods of use that extend the range of operation of the hollow cathodes to be suitable for plasma etch processes in semiconductor fabrication, particularly at advanced technology nodes, i.e., at smaller critical dimension sizes within the integrated circuitry.

In various embodiments described herein, different arrays of hollow cathodes are disclosed for use in plasma processing of a substrate, e.g., semiconductor wafer. During operation, a process gas is supplied to an array of hollow cathodes to generate plasma within each hollow cathode in the array. Then, the reactive constituents of the plasma are passed from the array of hollow cathodes to a low pressure environment within which the substrate is disposed, thereby allowing the reactive constituents to contact and do work on the substrate. Additionally, in some embodiments, the array of hollow cathodes are operated in a manner whereby ion processing and radical processing of the substrate are decoupled and independently controlled.

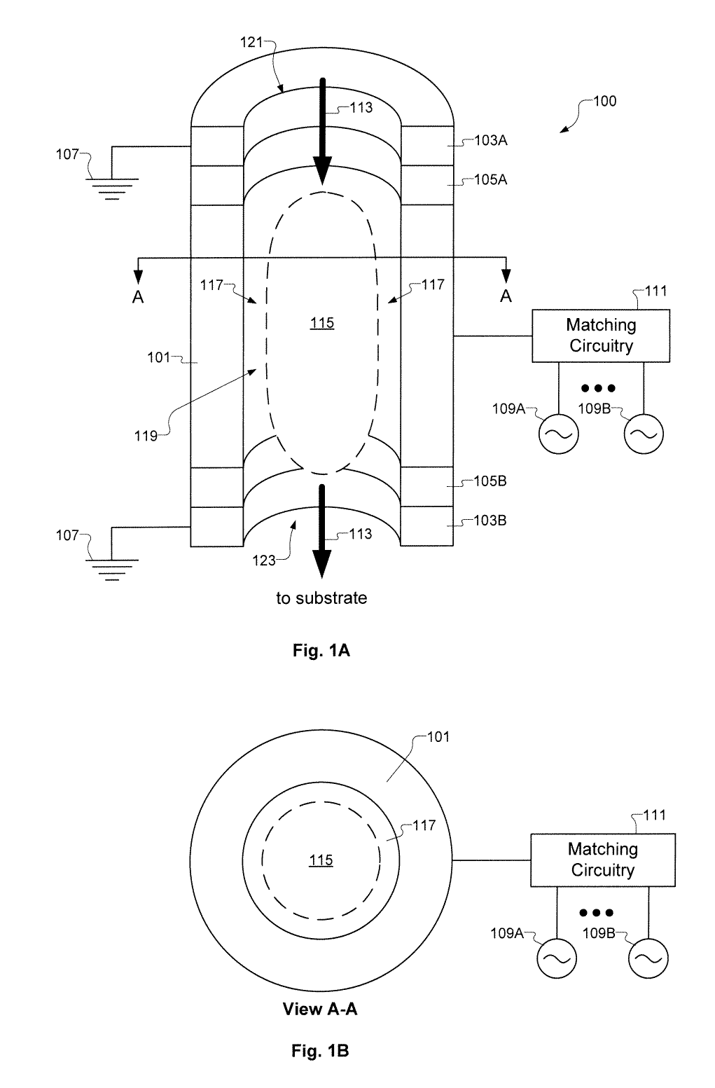

FIG. 1A shows a vertical cross-section of a hollow cathode assembly 100, in accordance with one embodiment of the present invention. In this example embodiment, the hollow cathode assembly 100 includes a hollow cylinder 101 of electrically conductive material. The hollow cathode assembly 100 also includes electrically conductive rings 103A, 103B disposed at each end of the hollow cylinder 101. The electrically conductive rings 103A, 103B are separated from the hollow cylinder 101 by dielectric rings 105A, 105B, respectively. Also, in this example embodiment, each of the electrically conductive rings 103A, 103B is electrically connected to a reference ground potential 107.

Multiple radiofrequency (RF) power sources 109A, 109B are connected to supply RF power to the hollow cylinder 101. More specifically, each of the multiple RF power sources 109A, 109B is connected to supply RF power through respective matching circuitry 111, to the hollow cylinder 101. The matching circuitry 111 is defined to prevent/mitigate reflection of the RF power from the hollow cylinder 101, such that the RF power will be transmitted through the hollow cylinder 101 to the reference ground potential 107. It should be understood that although the example embodiment of FIG. 1A shows two RF power sources 109A, 109B, other embodiments can utilize more than two RF power sources.

During operation, a process gas is flowed through an interior cavity of the hollow cathode assembly 100, as depicted by arrows 113. Also, during operation, RF power supplied to the hollow cylinder 101 from the multiple RF power sources 109A, 109B transforms the process gas into a plasma 115 within the hollow cylinder 101. In the plasma 115, the process gas is transformed to include both ionized constituents and radical species which may be capable of doing work on a substrate when exposed to the substrate. It should be appreciated that more than one RF power source 109A, 109B is used to supply RF power to the hollow cathode assembly 100. Each of the RF power sources 109A, 109B is independently controllable with regard to RF power frequency and amplitude.

The plasma 115 is confined within the hollow cylinder 101 by the electric field generated by the RF power supplied from the multiple RF power sources 109A, 109B. Also, a sheath 117 is defined within the hollow cylinder 101 about the plasma 115. FIG. 1B shows a horizontal cross-section of the hollow cathode assembly 100 corresponding to View A-A identified in FIG. 1A, in accordance with one embodiment of the present invention. As shown in FIG. 1B, the sheath 117 separates the plasma 115 from the interior surface of the hollow cylinder 101.

In contrast to the hollow cathode assembly 100 of FIGS. 1A-1B, conventional hollow cathode sources have been powered by either a single RF power source or by a direct current (DC) power source, but not both. Therefore, the operating range of the conventional hollow cathode source with regard to process gas pressure has been determined by a single power source and the particular configuration/dimensions of the hollow cathode source.

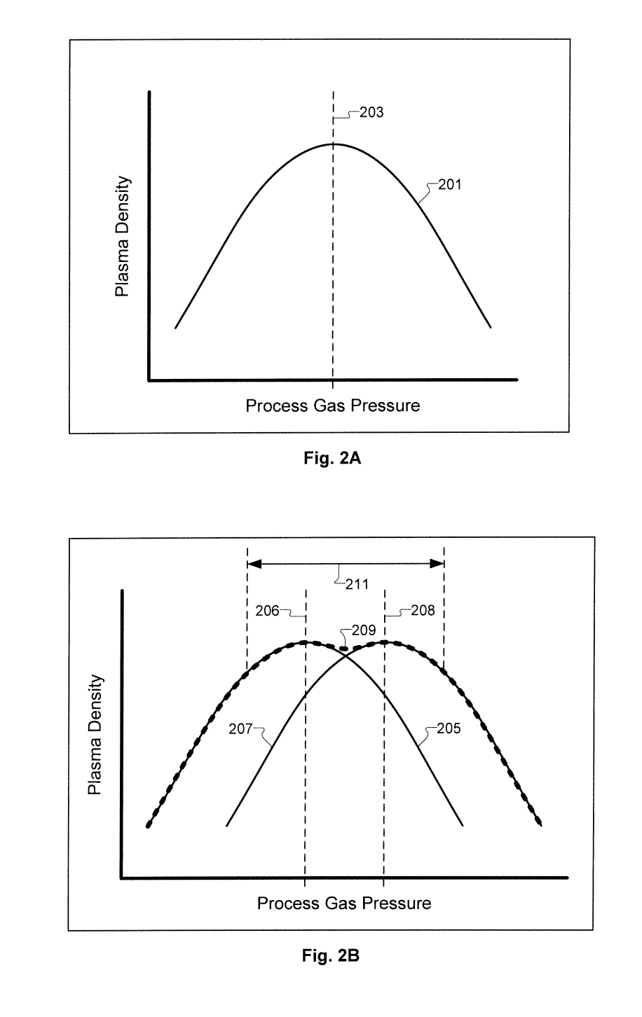

FIG. 2A shows a plasma density versus process gas pressure curve 201 for a hollow cathode of a given configuration and dimensions operating at either a single RF frequency or at DC. As shown in FIG. 2A, an optimal process gas pressure 203 corresponds to a peak plasma density. The plasma density falls as the process gas pressure is moved in either direction from the optimal process gas pressure 203. Therefore, at either the single RF frequency or DC, the hollow cathode of fixed configuration and dimensions is required to operate within a narrow process gas pressure range about the optimal process gas pressure 203. This narrow process gas pressure range can have limited usefulness in semiconductor fabrication processes that require a broader operational process gas pressure range.

FIG. 2B shows a plasma density versus process gas pressure curve 209 for the hollow cathode assembly 100 of FIGS. 1A-1B, in accordance with one embodiment of the present invention. The curve 209 includes a first component curve 205 corresponding to the first RF power source 109A, and a second component curve 207 corresponding to the second RF power source 109B. The first RF power source 109A generates a peak plasma density within a process gas pressure range about a first optimal process gas pressure 206. The second RF power source 109B generates a peak plasma density within a process gas pressure range about a second optimal process gas pressure 208. Because the second optimal process gas pressure 208 associated with the second RF power source 109B is greater than the first optimal gas pressure 206 associated with the first RF power source 109A, the effective plasma density versus process gas pressure curve 209 exhibits a broader effective pressure range 211 than what is achievable with either of the RF power sources 109A, 109B alone.

Therefore, it should be understood that use of multiple independent RF power sources at appropriate frequencies to power a hollow cathode can extend the operational range of the hollow cathode well beyond what is achievable with use of either a single RF frequency power source or DC power source. In following, use of multiple independent RF power sources at appropriate frequencies with an appropriately configured hollow cathode assembly can extend the effective process gas operational pressure range of the hollow cathode assembly, and thereby enable use of the hollow cathode assembly as a plasma source in semiconductor fabrication processes. Moreover, for a given hollow cathode assembly configuration, use of more than two RF power sources at different frequencies can substantially increase the effective process gas operational pressure range of the given hollow cathode assembly.

In one embodiment, two RF power frequencies are supplied to the hollow cathode assembly 100. In one instance of this embodiment, the two RF power frequencies are about 2 megaHertz (MHz) and about 60 MHz. In another embodiment, three RF power frequencies are supplied to the hollow cathode assembly 100. In one instance of this embodiment, one of the three RF power frequencies is within a range extending from about 100 kiloHertz (kHz) to about 2 MHz, and the other two RF power frequencies are about 27 MHz and about 60 MHz. In this embodiment, the lowest frequency is used to set up the hollow cathode effect. Also in this embodiment, the highest frequency is used to establish the initial plasma with the required sheath size. Also in this embodiment, the intermediate frequency is used to bridge process regimes and aid in making the plasma strike efficiently. This three RF power frequency embodiment provides for hollow cathode plasma generation at process gas pressures within a range extending from about one milliTorr (mTorr) to hundreds of mTorr. The upper end of the process gas pressure range (hundreds of mTorr) can be used for chamber cleaning operations. The lower end of the process gas pressure range (about one mTorr) can be used for plasma etching processes in advanced gate and contact fabrication operations.

In various embodiments, the multiple RF power frequencies supplied to the hollow cathode can be binned into five ranges. A first of the five ranges is DC. A second of the five ranges is referred to as a low range, and extends from hundreds of kHz to about 5 kHz. A third of the five ranges is referred to as a medium range, and extends from about 5 kHz to about 13 MHz. A fourth of the five ranges is referred to as a high range, and extends from about 13 MHz to about 40 MHz. A fifth of the five ranges is referred to as a very high range, and extends from about 40 MHz to more than 100 MHz. It should be understood that operation of the hollow cathode with different RF power frequency combinations may require different matching circuitry designs, various RF return current path considerations, and use of different inter-electrode dielectric material thicknesses.

With reference back to FIGS. 1A-1B, is should be understood that the combination of the hollow cathode assembly 100 with the multiple RF power sources 109A, 109B and their respective matching circuitry 111, represent a hollow cathode system for plasma generation in substrate plasma processing. In particular, the hollow cylinder 101 represents an electrically conductive member 101 shaped to circumscribe an interior cavity 119. The electrically conductive member 101 is formed to have a process gas inlet 121 in fluid communication with the interior cavity 119. The electrically conductive member 101 is also formed to have an opening 123 that exposes the interior cavity 119 to a substrate processing region.

The RF power source 109A represents a first RF power source 109A in electrical communication with the electrically conductive member 101, so as to enable transmission of a first RF power to the electrically conductive member 101. The RF power source 109B represents a second RF power source 109A in electrical communication with the electrically conductive member 101, so as to enable transmission of a second RF power to the electrically conductive member 101. The first and second RF power sources 109A, 109B are independently controllable, such that the first and second RF powers are independently controllable with regard to frequency and amplitude.

Further with regard to FIGS. 1A-1B, the electrically conductive ring 103A represents a first electrically grounded member 103A formed to circumscribe the process gas inlet 121. Also, the dielectric ring 105A represents a first dielectric spacer 105A formed to circumscribe the process gas inlet 121. The first dielectric spacer 105A is disposed between the first electrically grounded member 103A and the electrically conductive member 101. Similarly, the electrically conductive ring 103B represents a second electrically grounded member 103B formed to circumscribe the opening 123 that exposes the interior cavity 119 to the substrate processing region. Also, the dielectric ring 105B represents a second dielectric spacer 105B formed to circumscribe the opening 123 that exposes the interior cavity 119 to the substrate processing region. The second dielectric spacer 105B is disposed between the second electrically grounded member 103B and the electrically conductive member 101.

The matching circuitry 111 includes a first matching circuit connected between the first RF power source 109A and the electrically conductive member 101. The first matching circuit is defined to prevent reflection of the first RF power from the electrically conductive member 101. Also, the matching circuitry 111 includes a second matching circuit connected between the second RF power source 109B and the electrically conductive member 101. The second matching circuit is defined to prevent reflection of the second RF power from the electrically conductive member 101. In various embodiments, the hollow cathode system of FIGS. 1A-1B can include one or more additional RF power sources in electrical communication with the electrically conductive member 101, so as to enable transmission of additional corresponding RF powers to the electrically conductive member 101. The additional RF power sources are independently controllable with regard to frequency and amplitude.

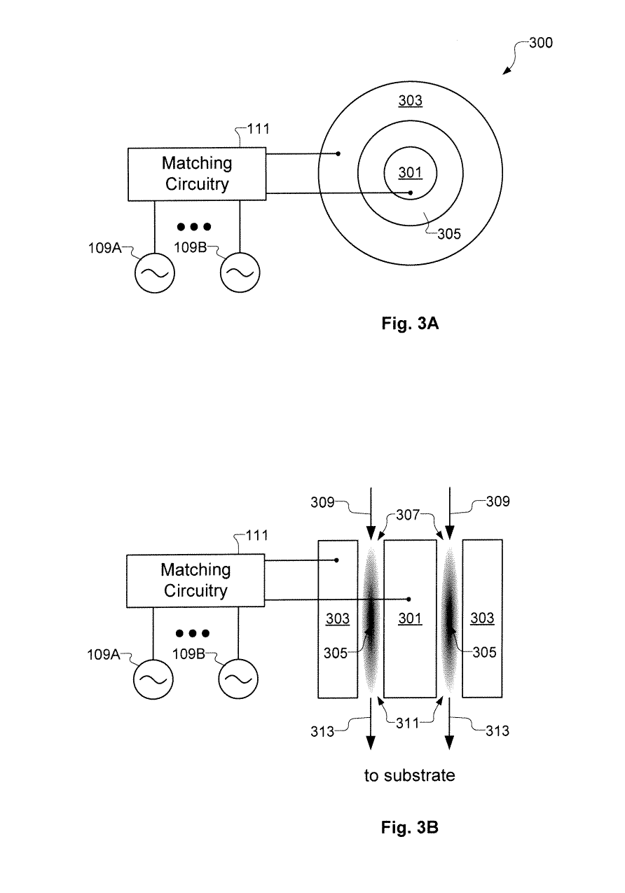

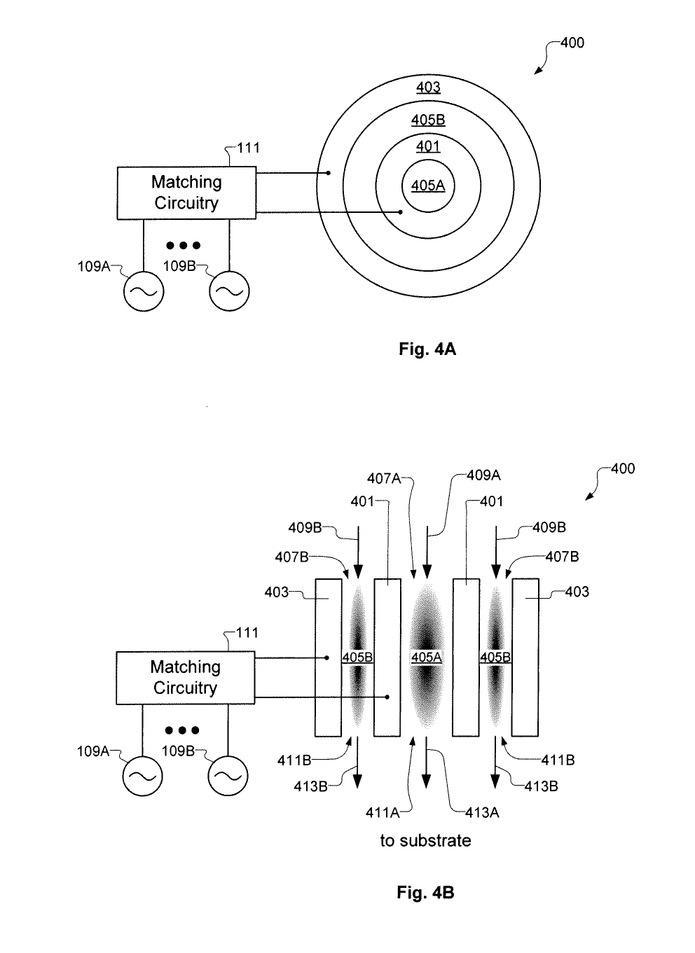

While the hollow cylinder 101 represents the electrically conductive member in the example embodiment of FIGS. 1A-1B, it should be understood that the electrically conductive member of the hollow cathode system can be shaped differently in other embodiments. FIGS. 3A-3B show an electrically conductive member 300 of a hollow cathode system that is formed in multiple parts, in accordance with one embodiment of the present invention. The electrically conductive member 300 includes a central solid cylinder 301, and an outer hollow cylinder 303, concentrically disposed with respect to each other. The central solid cylinder 301 and the outer hollow cylinder 303 are sized such that an interior cavity 305 is formed between the central solid cylinder 301 and the outer hollow cylinder 303.

As shown in FIG. 3B, the process gas flows through a process gas inlet 307 in fluid communication with the interior cavity 305, as indicated by arrows 309. Also, the electrically conductive member 300 is formed to have an opening 311 that exposes the interior cavity 305 to a substrate processing region. A plasma is generated within the interior cavity 305 of the electrically conductive member 300, such that reactive species and ions of the plasma can move from the interior cavity 305 through the opening 311 into the substrate processing region, as indicated by arrows 313.

In one embodiment, the first RF power source 109A is in electrical communication with the central solid cylinder 301, through appropriate matching circuitry 111. Also, in this embodiment, the second RF power source 109B is in electrical communication with the outer hollow cylinder 303, through appropriate matching circuitry 111. In another embodiment, both the first and second RF power sources 109A, 109B are in electrical communication with each of the central solid cylinder 301 and the outer hollow cylinder 303, through respective and appropriate matching circuitry 111.

FIGS. 4A-4B show an electrically conductive member 400 of a hollow cathode system that is formed in multiple parts, so as to segment an interior cavity into multiple interior cavities 405A, 405B, in accordance with one embodiment of the present invention. The electrically conductive member includes a central hollow cylinder 401 and an outer hollow cylinder 403 disposed in a concentric and spaced apart manner with respect to each other. The first interior cavity 405A is formed within the central hollow cylinder 401. The second interior cavity 405B is formed between the central hollow cylinder 401 and the outer hollow cylinder 403.

As shown in FIG. 4B, the process gas flows through a first process gas inlet 407A in fluid communication with the first interior cavity 405A, as indicated by arrow 409A. Also, the process gas flows through a second process gas inlet 407B in fluid communication with the second interior cavity 405B, as indicated by arrow 409B. The electrically conductive member 400 is further defined to have an opening 411A that exposes the first interior cavity 405A to a substrate processing region. Also, the electrically conductive member 400 is defined to have an opening 411B that exposes the second interior cavity 405B to the substrate processing region. A plasma is generated within the interior cavities 405A, 405B of the electrically conductive member 400, such that reactive species and ions of the plasma can move from the interior cavities 405A, 405B through their respective openings 411A, 411B, into the substrate processing region, as indicated by arrows 413A, 413B.

In one embodiment, the first RF power source 109A is in electrical communication with the central hollow cylinder 401, through appropriate matching circuitry 111. Also, in this embodiment, the second RF power source 109B is in electrical communication with the outer hollow cylinder 403, through appropriate matching circuitry 111. In another embodiment, both the first and second RF power sources 109A, 109B are in electrical communication with the central hollow cylinder 401, through appropriate matching circuitry 111. Also, in this embodiment, the second RF power source 109B is in electrical communication with the outer hollow cylinder 403, through appropriate matching circuitry 111. In yet another embodiment, both the first and second RF power sources 109A, 109B are in electrical communication with each of the central hollow cylinder 401 and the outer hollow cylinder 403.

In one embodiment, the first process gas inlet 407A of the first interior cavity 405A is in fluid communication with a first process gas source, and the second process gas inlet 407B of the second interior cavity 405B is in fluid communication with a second process gas source. In one version of this embodiment, the process gas inlets 407A, 407B of both the first and second interior cavities 405A, 405B are in fluid communication with a common process gas source. In another version of this embodiment, the first and second process gas sources are independently controllable with regard to process gas type, process gas pressure, process gas flow rate, process gas temperature, or any combination thereof.

In the embodiment of FIGS. 4A-4B, at least one of the central and outer hollow cylinders 401, 403 that is to be exposed to a higher pressure process gas within either of the interior cavities 405A, 405B is connected to a lower frequency one of the at least two independently controllable RF power sources 109A, 109B. Also, in this embodiment, at least one of the central and outer hollow cylinders 401, 403 that is to be exposed to a lower pressure process gas within the interior cavities 405A, 405B is connected to a higher frequency one of the at least two independently controllable RF power sources 109A, 109B.

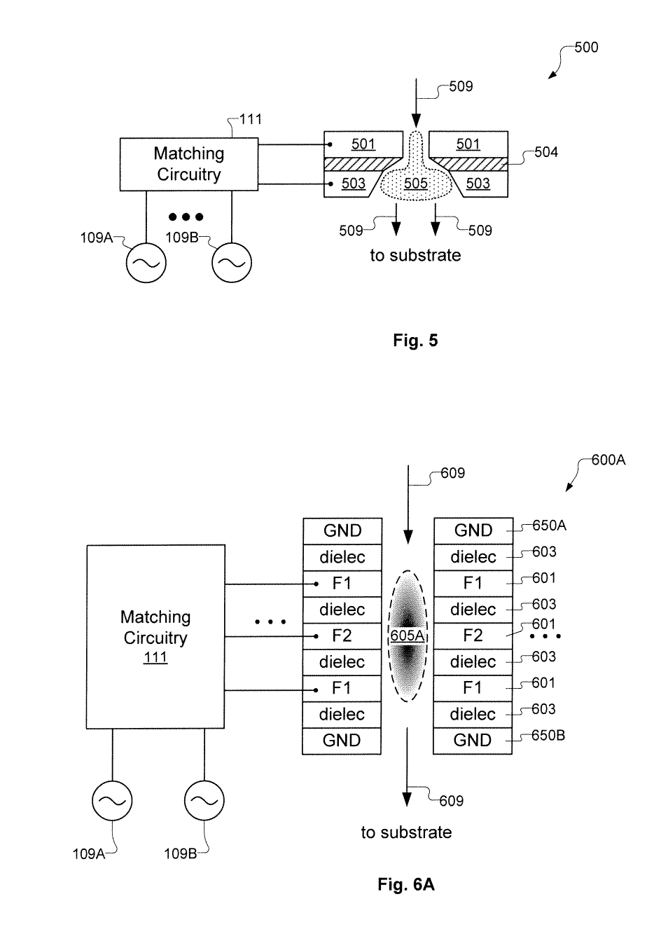

FIG. 5 shows a vertical cross-section through a multi-frequency RF powered hollow cathode 500, in which an interior cavity 505 of the hollow cathode 500 is shaped to affect process gas pressure, in accordance with one embodiment of the present invention. In the example embodiment of FIG. 5, the hollow cathode 500 includes a first electrically conductive member 501, and a second electrically conductive member 503, positioned in a sequential manner relative to a process gas flow path through the hollow cathode 500, as indicated by arrows 509. The first and second electrically conductive member 501, 503 are separated from each other by a dielectric material 504. A portion of the interior cavity 505 extending through the first electrically conductive member 501 is of smaller size to maintain a higher process gas pressure therein. However, a portion of the interior cavity 505 extending through the second electrically conductive member 503 is diffuser-shaped so as to reduce the process gas pressure therein.

Because higher process gas pressures require lower frequency RF power to generate an optimum plasma density, vice-versa, the first electrically conductive member 501 having the smaller sized portion of the interior cavity 505 may be connected to a lower frequency one of the RF power sources 109A, 109B. In a complementary manner, the second electrically conductive member 503 having the diffuser-shaped portion of the interior cavity 505 may be connected to a higher frequency one of the RF power sources 109A, 109B.

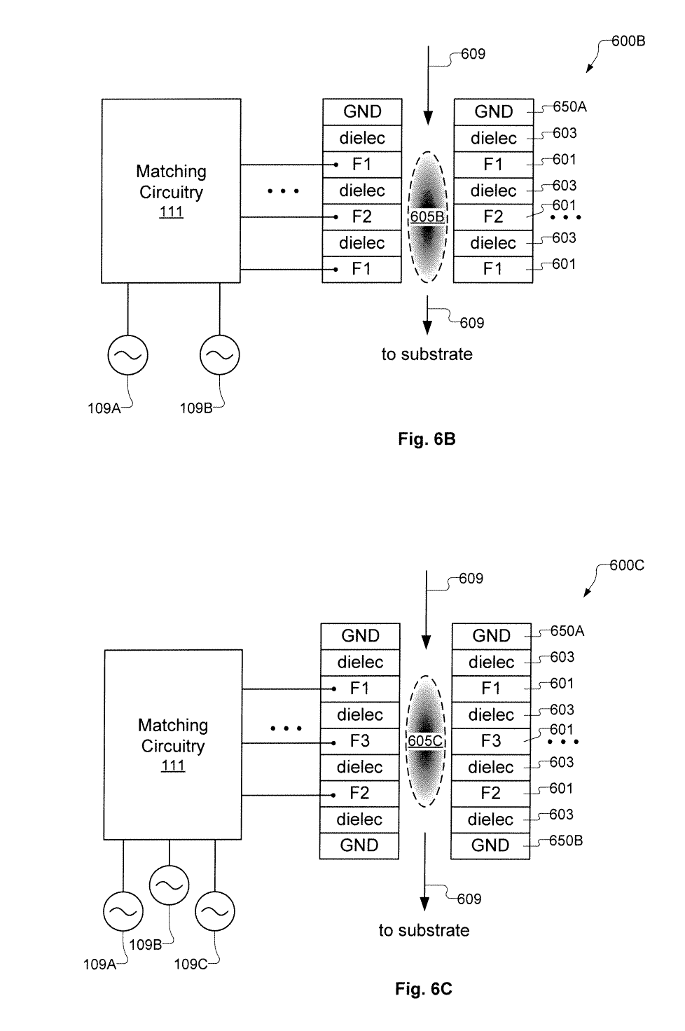

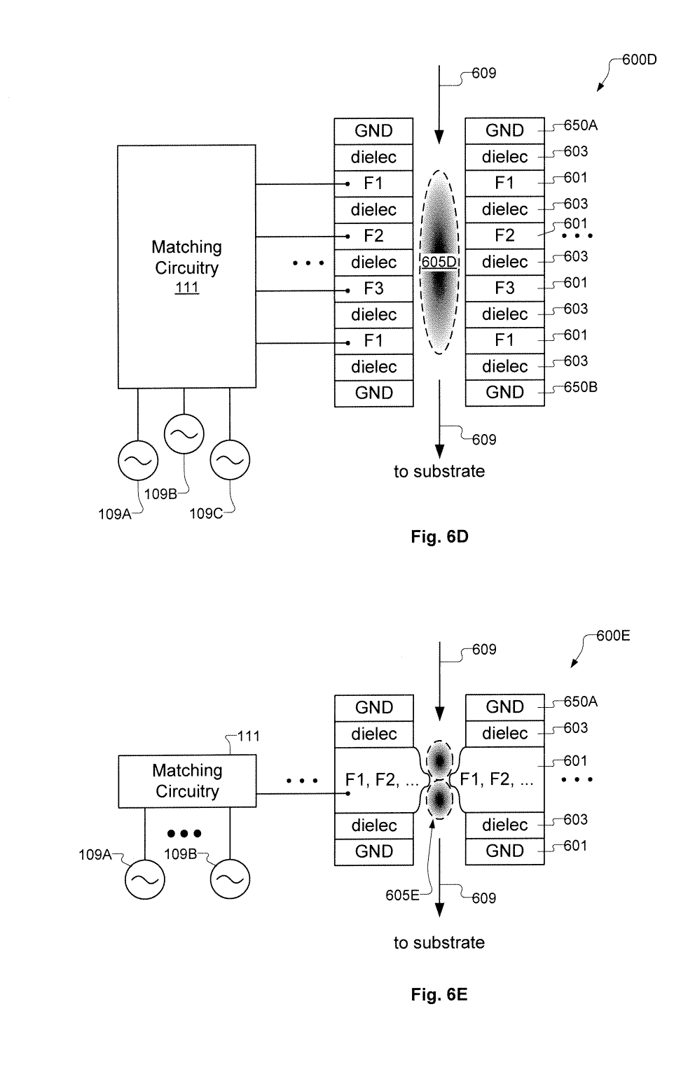

FIGS. 6A-6D show examples of multi-frequency RF powered hollow cathodes 600A-600D in which electrically conductive members are positioned in a sequential manner relative to a process gas flow path, as indicated by arrow 609. In various embodiments, the hollow cathodes 600A-600D include a stack of multiple electrically conductive cathode plates 601 separated from each other by dielectric sheets 603. Holes are formed through the stack of electrically conductive cathode plates 601 and dielectric sheets 603 to form the interior cavities of the hollow cathodes 600A-600D through which the process gas flows, as indicated by arrows 609. It should be understood that each of FIGS. 6A-6D shows a vertical cross-section through one of multiple hollow cathodes formed within a corresponding stack of electrically conductive cathode plates 601 and dielectric sheets 603.

In the example embodiments of FIGS. 6A-6D, each of the multiple cathode plates 601 is connected to receive RF power from one or more of at least two independently controllable RF power sources 109A, 109B, through appropriate matching circuitry 111. The process gas within the interior cavities 605A-605D of the hollow cathodes 600A-600D is transformed into plasma by the RF power emitted from the cathode plates 601.

FIG. 6A shows the example hollow cathode 600A in which three electrically conductive cathode plates 601 are disposed and separated from each other by dielectric sheets 603, in accordance with one embodiment of the present invention. In FIG. 6A, two independently controlled RF power sources 109A, 109B are used to supply RF power to the cathode plates 601 at two different frequencies F1, F2, e.g., at a low frequency F1 and at a high frequency F2, vice-versa. The embodiment of FIG. 6A also includes an upper ground plate 650A and a lower ground plate 650B, to provide return paths for the RF power emitted from the cathode plates 601. The ground plates 650A, 650B are separated from their neighboring cathode plates 601 by dielectric sheets 603. Also, the ground plates 650A, 605B have holes formed therein to match the holes formed within the cathode plates 601 and dielectric sheets 603.

It should be understood that not all embodiments are required to include upper and lower ground plates 650A, 605B. For instance, other structures within a plasma processing chamber around the hollow cathodes may provide a suitable RF power return path. For example, FIG. 6B shows the example hollow cathode 600B, as a variation of the hollow cathode 600A of FIG. 6A, in which the lower ground plate 650B is absent, in accordance with one embodiment of the present invention. FIG. 6C shows the example hollow cathode 600C, as a variation of the hollow cathode 600A of FIG. 6A, in which three independently controlled RF power sources 109A, 109B, 109C are used to supply RF power to the cathode plates 601 at three different frequencies F1, F2, F3, i.e., at the low frequency F1, at a medium frequency F3, and at the high frequency F2, in accordance with one embodiment of the present invention.

FIG. 6D shows the example hollow cathode 600D in which four electrically conductive cathode plates 601 are disposed and separated from each other by dielectric sheets 603, in accordance with one embodiment of the present invention. In FIG. 6D, three independently controlled RF power sources 109A, 109B, 109C are used to supply RF power to the cathode plates 601 at three different frequencies F1, F2, F3, i.e., at the low frequency F1, at the medium frequency F3, and at the high frequency F2. It should be understood that the hollow cathode configurations of FIGS. 6A-6D are provided way of example, and do not represent an exhaustive set of possible hollow cathode configurations. In other embodiments, hollow cathodes can be formed in a manner similar to those depicted in FIGS. 6A-6D, but may include a different number of cathode plates 601, may utilize a different number of RF power frequencies, and may or may not utilize upper and/or lower ground plates 650A, 650B.

Additionally, in some embodiments, multiple RF power frequencies can be applied to a single cathode plate 601. For example, in a hollow cathode that includes multiple cathode plates 601, one or more of the multiple cathode plates 601 may be individually connected to receive multiple RF power frequencies. FIG. 6E shows an example hollow cathode 600E in which a single electrically conductive cathode plate 601 is connected to receive multiple RF power frequencies F1, F2, etc., in accordance with one embodiment of the present invention. FIG. 6E also shows how the cathode plate 601 can be defined to include a shaped interior cavity 605E to affect process gas flow and/or pressure. It should be understood that the holes formed through the cathode plates 601, in the example embodiments of FIGS. 6A-6E, can be defined in many different ways to influence process gas flow rate and/or pressure variation along the process gas flow paths through the hollow cathodes.

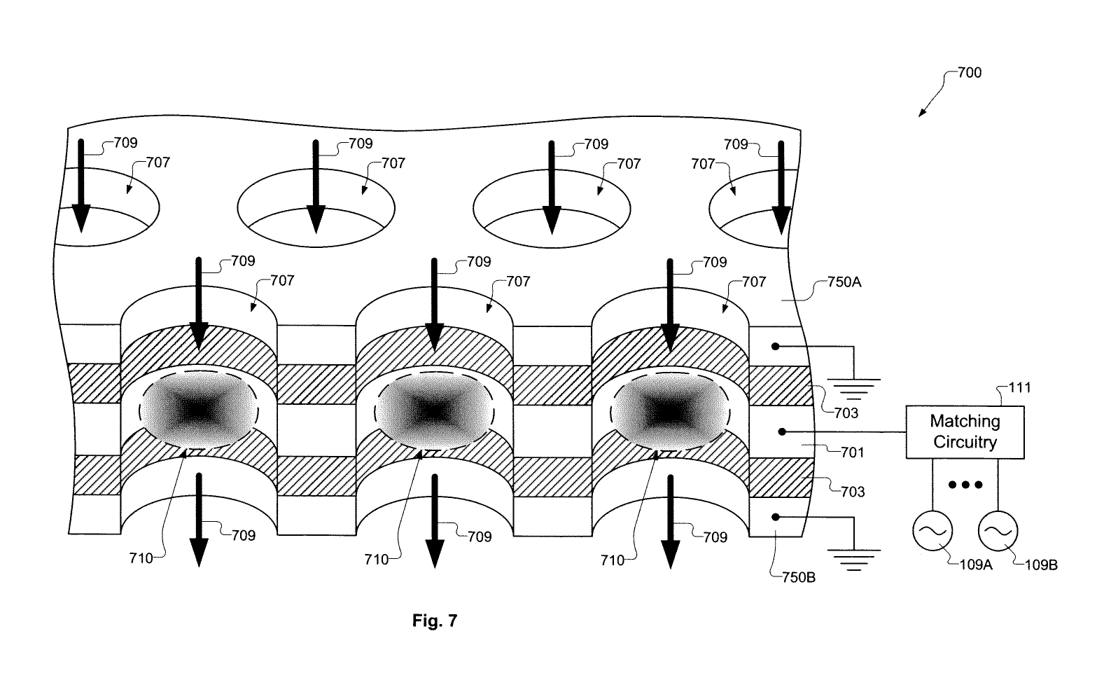

FIG. 7 shows a hollow cathode system 700 for plasma generation in substrate plasma processing, in accordance with one embodiment of the present invention. The hollow cathode system includes a plurality of electrically conductive plates 701, 750A, 750B stacked in a layered manner. The hollow cathode system 700 also includes dielectric sheets 703 disposed between each adjacently positioned pair of the plurality of electrically conductive plates 701, 750A, 750B. A number of holes 707 are formed to extend through the plurality of electrically conductive plates 701, 750A, 750B and dielectric sheets 703 disposed there between. Each hole 707 forms an interior cavity of a hollow cathode. More specifically, the portion of each hole 707 that passes through an RF powered electrically conductive plate 701 forms an interior cavity of a hollow cathode.

In the hollow cathode system 700, at least two independently controllable RF power sources 109A, 109B are electrically connected to the electrically conductive plate 701. Each of the at least two independently controllable RF power sources 109A, 109B is independently controllable with regard to RF power frequency and amplitude. In the example embodiment of FIG. 7, the hollow cathode system 700 includes a top ground plate 750A, a central cathode plate 701 connected to receive RF power from each of the at least two independently controllable RF power sources 109A, 109B, and a bottom ground plate 750B. It should be understood that in other embodiments, the hollow cathode system 700 can include multiple RF powered electrically conductive plates, such as described with regard to FIGS. 6A-6D. Also, in other embodiments, the hollow cathode system 700 may include only the top ground plate 750A, only the bottom ground plate 750B, or neither the top nor bottom ground plates 750A, 750B.

When deployed in a plasma processing system, a first end of each of the number of holes 707 is in fluid communication with a process gas source. And, a second end of each of the number of holes 707 is in fluid communication with a substrate processing region. In this manner the process gas flows through holes 707, as indicated by arrows 709. As the process gas flows through the holes 707, RF powers emitted from the central cathode plate 701 transforms the process gas into plasma 710 within each hole 707. It should be understood that a pressure of the process gas within the hole 707 may suitable for plasma production within an RF power frequency range corresponding to less than all of the at least two independently controllable RF power sources 109A, 109B. However, as long as at least one of the RF power sources 109A, 109B is operated at a frequency suitable for plasma production with the supplied process gas pressure, the other RF power frequencies can be utilized to influence the plasma characteristics, i.e., the ion and/or radical generation within the plasma.

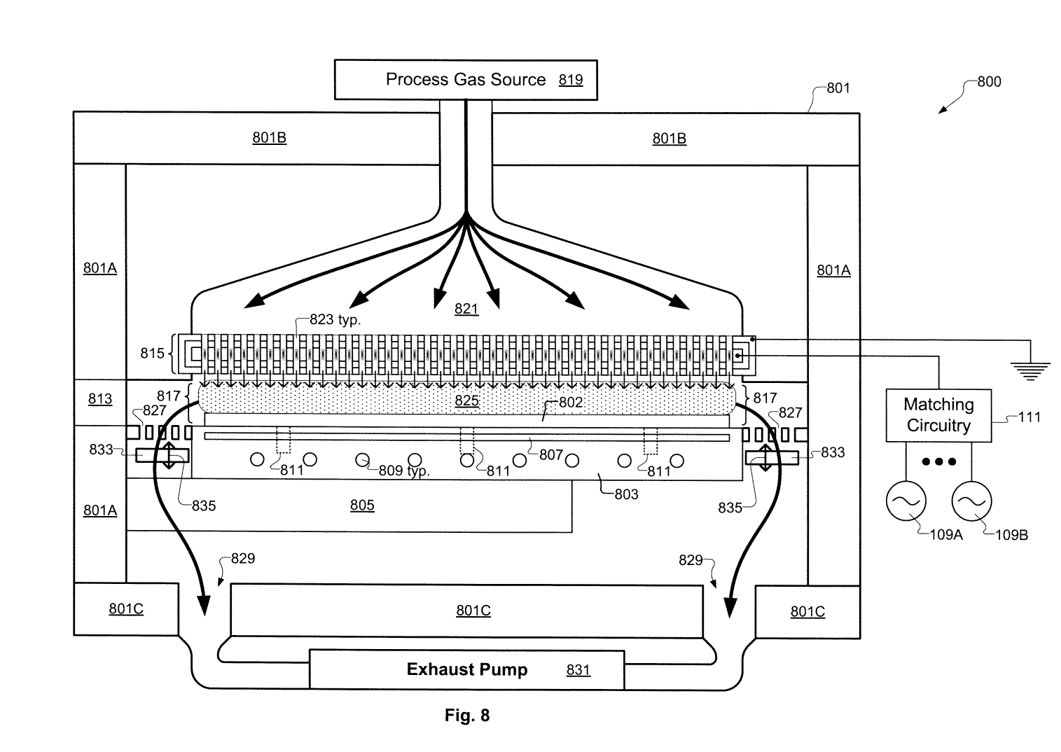

FIG. 8 shows a system 800 for substrate plasma processing, in accordance with one embodiment of the present invention. The system 800 includes a chamber 801 formed by surrounding walls 801A, a top plate 801B, and a bottom plate 801C. In various embodiments, the chamber walls 801A, top plate 801B, and bottom plate 801C can be formed from different materials, such as stainless steel or aluminum, by way of example, so long as the chamber 801 materials are structurally capable of withstanding pressure differentials and temperatures to which they will be exposed during plasma processing, and are chemically compatible with the plasma processing environment.

The system 800 also includes a substrate support 803 disposed within the chamber 801. The substrate support 803 is defined to hold a substrate 802 thereon during performance of a plasma processing operation on the substrate. In the embodiment of FIG. 8, the substrate support 803 is held by a cantilevered arm affixed to a wall 801A of the chamber 801. However, in other embodiments, the substrate support 803 can be affixed to the bottom plate 801C of the chamber 801 or to another member disposed within the chamber 801. In various embodiments, the substrate support 803 can be formed from different materials, such as stainless steel, aluminum, or ceramic, by way of example, so long as the substrate support 803 material is structurally capable of withstanding pressure differentials and temperatures to which it will be exposed during plasma processing, and is chemically compatible with the plasma processing environment.

In one embodiment, the substrate support 803 includes a bias electrode 807 for generating an electric field to attract ions toward the substrate support 803, and thereby toward the substrate 802 held on the substrate support 803. Also, in one embodiment, the substrate support 803 includes a number of cooling channels 809 through which a cooling fluid can be flowed during plasma processing operations to maintain temperature control of the substrate 802. Also, in one embodiment, the substrate support 803 can include a number of lifting pins 811 defined to lift and lower the substrate 802 relative to the substrate support 803. In one embodiment, a door assembly 813 is disposed within the chamber wall 801A to enable insertion and removal of the substrate 802 into/from the chamber 801. Additionally, in one embodiment, the substrate support 803 is defined as an electrostatic chuck equipped to generate an electrostatic field for holding the substrate 802 securely on the substrate support 803 during plasma processing operations.

The system 800 further includes a hollow cathode assembly 815 disposed within the chamber 801 above and spaced apart from the substrate support 803, so as to be positioned above and spaced apart from the substrate 802 when positioned on the substrate support 803. A substrate processing region 817 exists between the hollow cathode assembly 815 and the substrate support 803, so as to exist over the substrate 802 when positioned on the substrate support 803. In one embodiment, a vertical distance as measured perpendicularly between the hollow cathode assembly 815 and the substrate support 803, i.e., process gap, is within a range extending from about 1 centimeter (cm) to about 10 cm. In one embodiment, the vertical distance as measured perpendicularly between the hollow cathode assembly 815 and the substrate support 803 is about 5 cm. Also, in one embodiment, a vertical position of the substrate support 803 relative to the hollow cathode assembly 815, vice-versa, is adjustable either during performance of the plasma processing operation or between plasma processing operations.

The system 800 further includes a process gas source 819 in fluid communication with the hollow cathode assembly 815, to supply process gas to the hollow cathode assembly 815. In the example embodiment of FIG. 8, a process gas plenum 821 is formed within the chamber 801 above the hollow cathode assembly 815. The process gas plenum 821 is in fluid communication with both the process gas source 819 and each of multiple hollow cathodes 823 within the hollow cathode assembly 815. The process gas plenum 821 is formed to distribute the process gas to each of the multiple hollow cathodes 823 within the hollow cathode assembly 815 in a substantially uniform manner.

The system 800 also includes a plurality of RF power sources 109A, 109B in electrical communication with the hollow cathode assembly 815. Each of the plurality of RF power sources 109A, 109B is independently controllable with regard to RF power frequency and amplitude. Also, RF power is transmitted from each of the RF power sources 109A, 109B through respective matching circuitry 111 to ensure efficient RF power transmission through the hollow cathode assembly 815. During operation of the system 800, a plurality of RF powers are respectively transmitted from the plurality of RF power sources 109A, 109B to the hollow cathode assembly 815. The process gas is transformed into a plasma within each of the multiple hollow cathodes 823 of the hollow cathode assembly 815. Reactive species 825 within the plasma move from the hollow cathode assembly 815 to the substrate processing region 817 over the substrate support 803, i.e., onto the substrate 802 when disposed on the substrate support 803.

In one embodiment, upon entering the substrate processing region 817 from the hollow cathode assembly 815, the used process gas flows through peripheral vents 827, and is pumped out through exhaust ports 829 by an exhaust pump 831. In one embodiment, a flow throttling device 833 is provided to control a flow rate of the used process gas from the substrate processing region 817. In one embodiment, the flow throttling device 833 is defined as a ring structure that is movable toward and away from the peripheral vents 827, as indicated by arrows 835.

The hollow cathode assembly 815 is defined over an area of the substrate support 803 upon which the substrate 802 is to be received for plasma processing. The multiple hollow cathodes 823 of the hollow cathode assembly 815 are defined in exposure to the substrate processing region 817. The multiple hollow cathodes 823 are distributed in a substantially uniform manner relative to the area of the substrate support 803 upon which the substrate 802 is to be received for plasma processing. In one embodiment, about 100 hollow cathodes 823 are distributed in a substantially uniform manner relative to the area of the substrate support 803 upon which the substrate 802 is to be received for plasma processing. However, it should be understood that other embodiments may utilize more or less hollow cathodes 823. In the example embodiment of FIG. 8, the hollow cathode assembly 815 is essentially equivalent to the hollow cathode system 700 described with regard to FIG. 7. However, it should be appreciated that many different variations of the hollow cathode assembly 815 can be implemented within the system 800 of FIG. 8, such as those previously discussed with regard to FIGS. 1A through 6E.

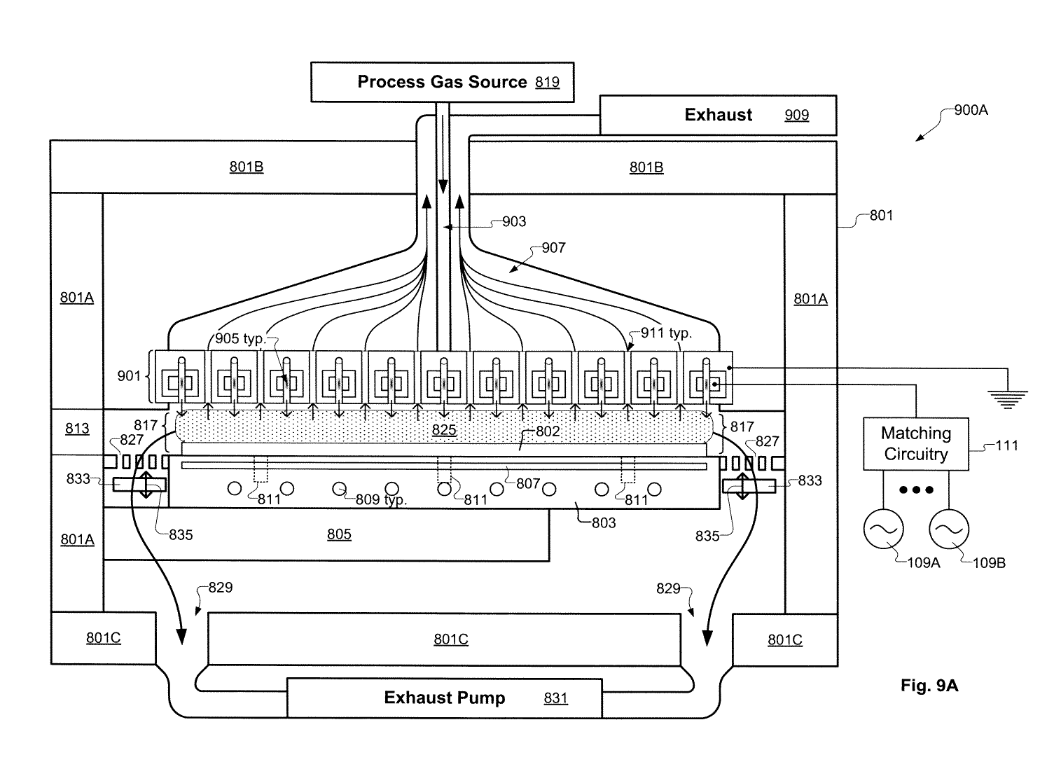

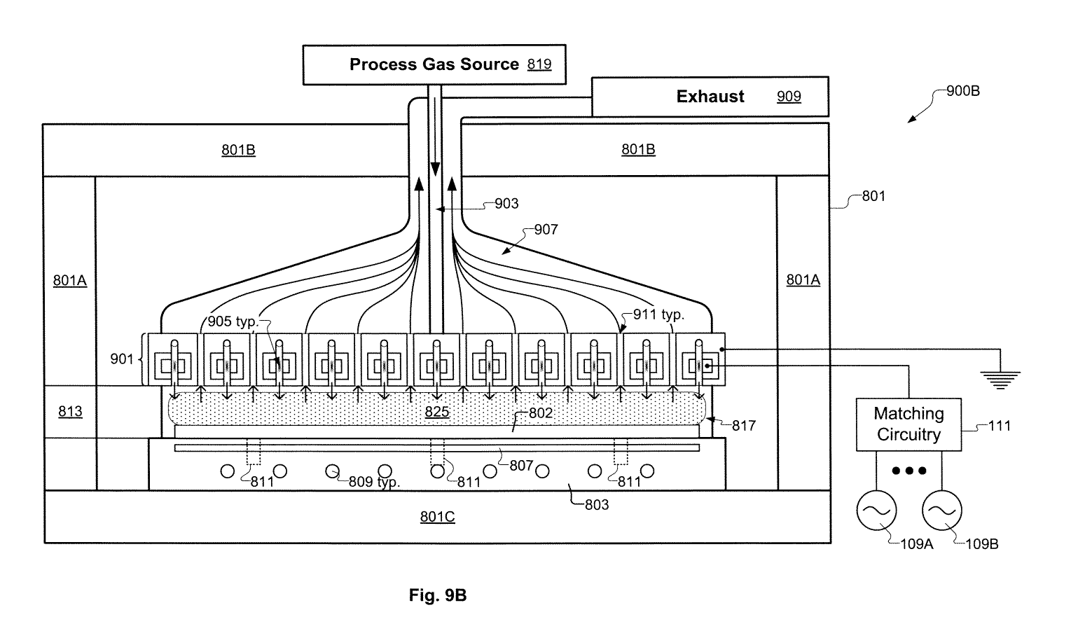

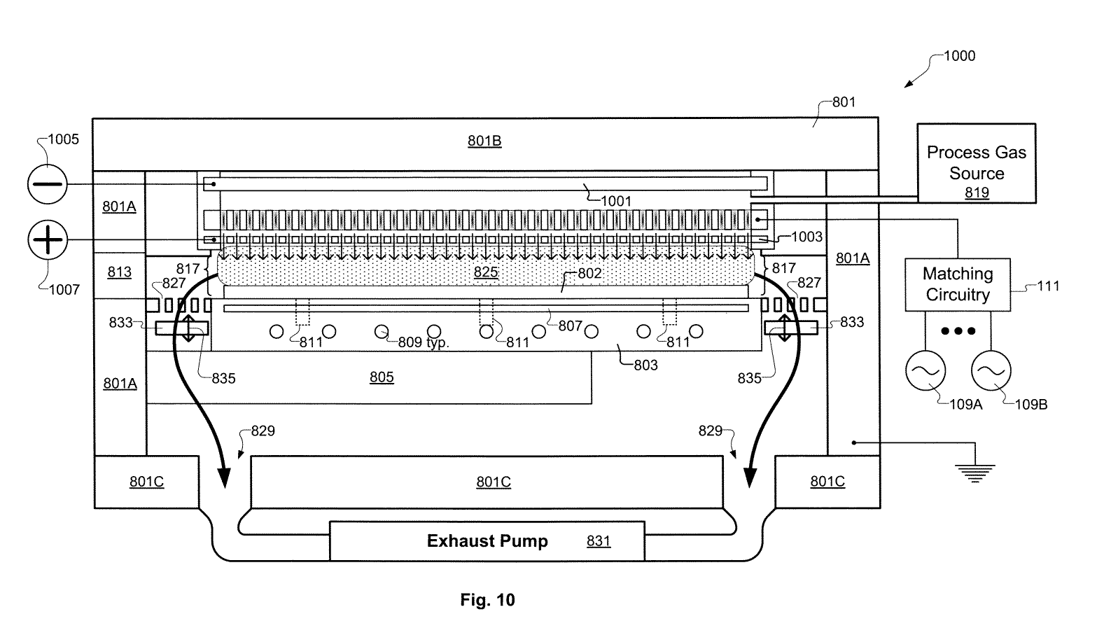

FIG. 9A shows another system 900A for substrate plasma processing, in accordance with one embodiment of the present invention. The system 900A is essentially equivalent to the system 800 of FIG. 8 with regard to the chamber 801, the substrate support 803, the peripheral vents 827, flow throttling device 833, exhaust ports 829, and exhaust pump 831. However, the system 900A includes a hollow cathode assembly 901 that is different from the hollow cathode assembly 815 of system 800. Specifically, the hollow cathode assembly 901 is formed to include process gas distribution channels (interior to the hollow cathode assembly 901) in fluid communication with a process gas supply line 903. The process gas supply line 903 is connected in fluid communication between the process gas source 819 and the hollow cathode assembly 901. The process gas distribution channels within the hollow cathode assembly 901 are fowled to direct the process gas from the process gas supply line 903 to each of multiple hollow cathodes 905 formed within the hollow cathode assembly 901, in a substantially uniform manner.

The system 900A further includes an exhaust plenum 907 formed within the chamber 801 above the hollow cathode assembly 901. The exhaust plenum 907 is fluidly connected to an exhaust pump 909. The hollow cathode assembly 901 includes multiple exhaust holes 911 formed to extend completely through the hollow cathode assembly 901 from the substrate processing region 817 to the exhaust plenum 907. The multiple exhaust holes 911 are distributed in a substantially uniform manner relative to the area of the substrate support 803 upon which the substrate 802 is to be received for plasma processing. Also, each of the multiple exhaust holes 911 is isolated from the multiple hollow cathodes 905 and the process gas distribution channels within the hollow cathode assembly 901. It should be appreciated that the vertical pump out capability afforded by the multiple exhaust holes 911 within the hollow cathode assembly 901 provides for improved control over reactive species residence time on the substrate 802, as a function of radial position on the substrate.

FIG. 9B shows a system 900B for substrate plasma processing that is a variation of the system 900A of FIG. 9A, in accordance with one embodiment of the present invention. The system 900B does not utilize the peripheral vents 827 and lower exhaust ports 829. Rather, in the system 900B, during operation, the substrate processing region 817 is fluidly sealed between the substrate support 803 and hollow cathode assembly 901, such that the exhaust from the substrate processing region 817 is required to travel through the exhaust holes 911 of the hollow cathode assembly 901.

FIG. 10 shows a system 1000 for substrate plasma processing that is a variation of the system 800 of FIG. 8, in accordance with one embodiment of the present invention. In the system 1000, the process gas plenum 821 is defined to accommodate an anode plate 1001. More specifically, the anode plate 1001 is disposed within the process gas plenum 821 and over the hollow cathode assembly 815. The anode plate 1001 is electrically connected to a negative bias 1005 so as to drive ions from the multiple hollow cathodes 823 into the substrate processing region 817. Also, in one embodiment, the system 1000 includes a cathode plate 1003 disposed between the hollow cathode assembly 815 and the substrate processing region 817. The cathode plate 1003 is electrically connected to a positive bias 1007 to pull ions from the multiple hollow cathodes 823 into the substrate processing region 817. It should be understood that different embodiments may include the anode plate 1001 alone, the cathode plate 1003 alone, or both the anode and cathode plates 1001, 1003.

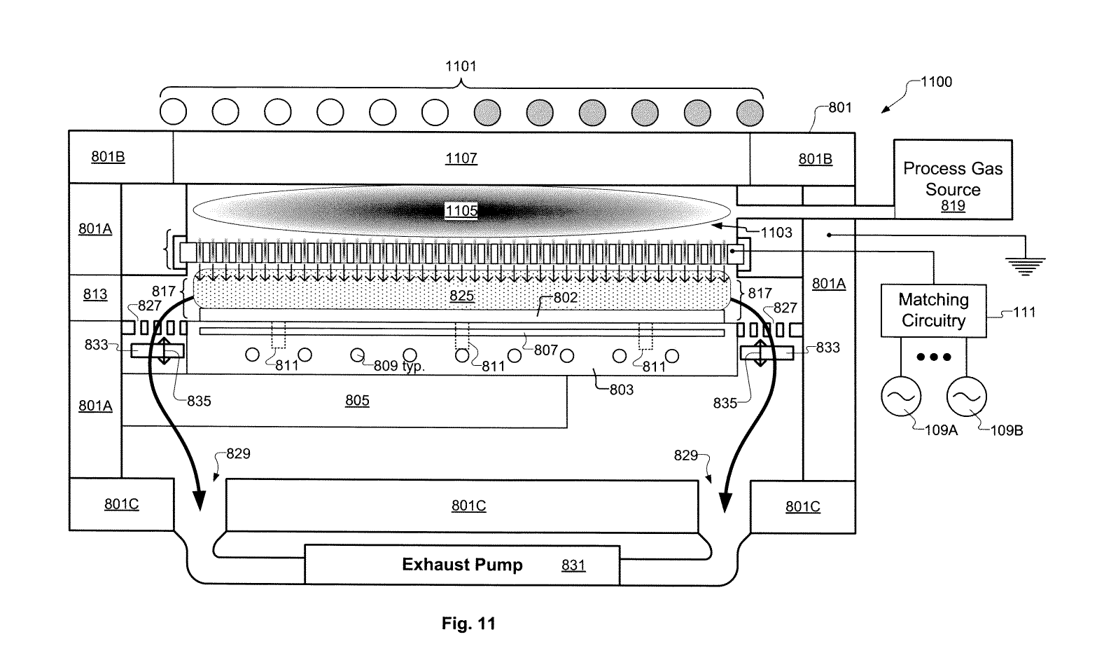

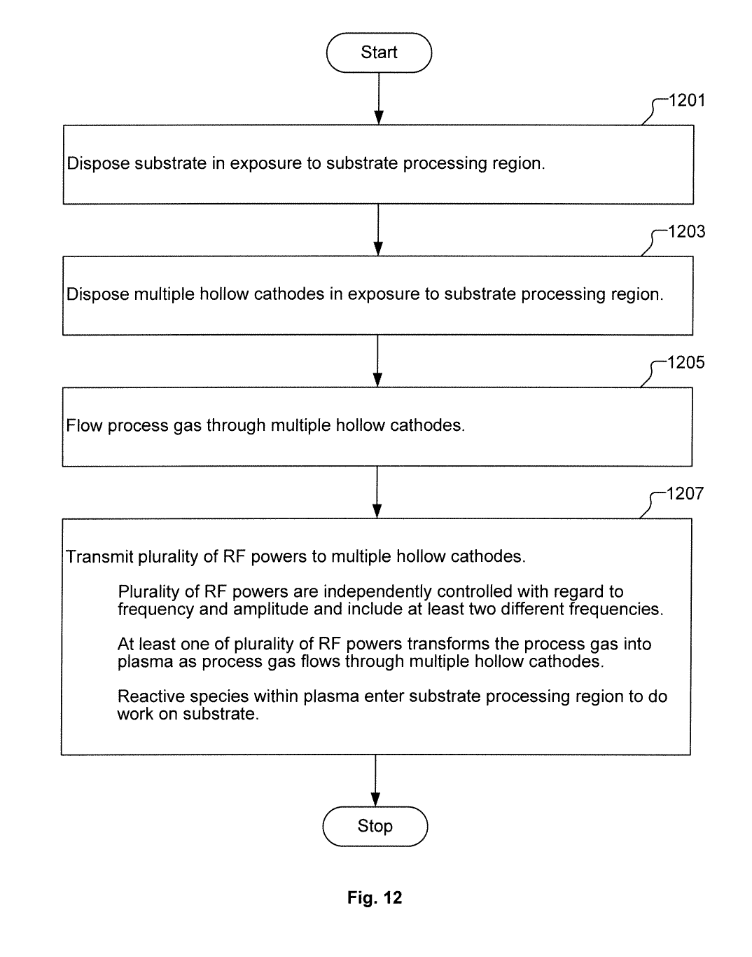

FIG. 11 shows a system 1100 for substrate plasma processing that is a variation of the system 800 of FIG. 8, in accordance with one embodiment of the present invention. The system 1100 is defined to have a source plasma region 1103, in place of the process gas plenum 821 in the system 800. Specifically, the source plasma region 1103 is formed within the chamber 801 above the hollow cathode assembly 815. The source plasma region 1103 is in fluid communication with both the process gas source 819 and each of the multiple hollow cathodes 823 within the hollow cathode assembly 815. The system 1100 also includes a coil assembly 1101 disposed to transform the process gas within the source plasma region 1103 into a source plasma 1105. In the system 1100, the chamber 801 top plate 801B is modified to include a window 1107 that is suitable for transmission of RF power from the coil assembly 1101 into the source plasma region 1103. In one embodiment, the window 1107 is formed from quartz. In another embodiment, the window 1107 is formed from a ceramic material, such as silicon carbide. In the system 1100, the source plasma 1105 drives secondary plasma generation in each of the multiple hollow cathodes 823 within the hollow cathode assembly 815, in a substantially uniform manner.

FIG. 12 shows a method for substrate plasma processing, in accordance with one embodiment of the present invention. It should be understood that the method of FIG. 12 can be implemented within either of the plasma processing systems 800, 900A, 900B, 1000, 1100 of FIGS. 8-11, and with either of the hollow cathode embodiments described with regard to FIGS. 1A-11. The method includes an operation 1201 for disposing a substrate in exposure to a substrate processing region. The method also includes an operation 1203 for disposing multiple hollow cathodes in exposure to the substrate processing region. In one embodiment, a number of the multiple hollow cathodes is within a range extending from about 25 to about 100. The method also includes an operation 1205 for flowing a process gas through the multiple hollow cathodes.

In an operation 1207, a plurality of RF powers are transmitted to the multiple hollow cathodes. The plurality of RF powers are independently controlled with regard to frequency and amplitude, and include at least two different frequencies. Also, at least one of the plurality of RF powers transforms the process gas into a plasma as the process gas flows through the multiple hollow cathodes. Reactive species within the plasma enter the substrate processing region to do work on the substrate.

In one embodiment, the plurality of RF powers include two or more frequencies from the group consisting of 2 megaHertz (MHz), 27 MHz, 60 MHz, and 200 kiloHertz (kHz). In other embodiments, the plurality of RF powers include at least two different RF power frequencies corresponding to one or more of a low range, medium range, high range, and very high range. The low frequency range extends from hundreds (100's) of kHz to about 5 kHz. The medium range extends from about 5 kHz to about 13 MHz. The high range extends from about 13 MHz to about 40 MHz. The very high range extends from about 40 MHz to more than 100 MHz.

The method can further include an operation for controlling a pressure of the process gas. In one embodiment, the pressure of the process gas enables formation of the plasma by some of the plurality of RF powers and does not enable formation of the plasma by others of the plurality of RF powers. In one embodiment, the pressure of the process gas is controlled within a range extending from about 1 milliTorr (mTorr) to about 500 mTorr. The method can also include an operation for setting a process gap distance, as measured perpendicularly between the substrate and the multiple hollow cathodes, within a range extending from about 1 cm to about 10 cm.

It should be appreciated that simultaneous use of multiple RF power frequencies/amplitudes, in combination with the hollow cathode embodiments described herein, can advantageously provide an ability to preferentially control generation of different types of reactive species within the plasma. For example, application of an RF power within the above-mentioned low frequency range can be used to promote generation of ions in the plasma. And, application of an RF power within the above-mentioned high frequency range can be used to promote generation of radicals in the plasma. In following, application of multiple RF powers including a combination of low and high frequencies at appropriate amplitudes can be used to generate a particular mixture of ions and radicals in the plasma that is suitable for a specific plasma processing operation.

Considering the foregoing, the method of FIG. 12 can include an operation for controlling frequency and amplitude of a first set of one or more RF powers of the plurality of RF powers so as to promote generation of a first type of reactive species within the plasma. The method can also include an operation for controlling frequency and amplitude of a second set of one or more RF powers of the plurality of RF powers so as to promote generation of a second type of reactive species within the plasma. In one embodiment, the first type of reactive species is ions, and the second type of reactive species is radicals. In this embodiment, the frequency of the first set of one or more RF powers is lower than the frequency of the second set of one or more RF powers. For example, in one embodiment, the frequency of the first set of one or more RF powers can be within the above-mentioned low frequency range, and the frequency of the second set of one or more RF powers can be within the above-mentioned high frequency range.

Numerous multi-frequency RF powered hollow cathode embodiments are disclosed herein that enable use of hollow cathode systems at lower process gas pressures suitable for use in semiconductor fabrication processes, such as plasma etching processes. The hollow cathode structures disclosed herein can be driven at high frequency, e.g., 60 MHz, and low frequency, e.g., 2 MHz or less, to provide for a sustained plasma within the hollow cathodes at low pressure, while also generating high enough plasma density. In this situation, the high frequency RF power component can strike and drive the plasma, while the low frequency RF component can provide for decreased plasma sheath size relative to the hollow cathode interior cavity size. In this situation, the saddle field of the hollow cathode may be parallel to the plane of the hollow cathode electrode.

As discussed herein, in one embodiment, two or more RF power frequencies can be used to drive a common electrode within the hollow cathode assembly. In another embodiment, a high frequency RF powered electrode can be sandwiched between low frequency RF powered electrodes, such that a saddle field exists along an axis of the hollow cathode interior cavity, when the low frequency RF powered electrodes are operated in phase.

Some hollow cathodes may require higher process gas pressures during operation. In this case, in one embodiment, a hollow cathode array can be immersed between low frequency RF powered electrodes driven either in phase or out of phase. In this embodiment, the low frequency RF powered electrode provides a high pressure environment above the lower pressure substrate processing region. When driven in phase and close to the hollow cathode array, the low frequency RF powered electrodes generate a saddle field therebetween and along the axes of the hollow cathodes within the hollow cathode array. When drive out of phase, i.e., in a push-pull relationship, the low frequency RF powered electrodes generate a saddle field on a side of the hollow cathode array facing the instantaneous anode. This out of phase configuration can be exploited to insert ions and electrons into the low pressure substrate processing region.

In one embodiment, the hollow cathodes are configured to include a pinch off point having low enough conductance to sustain a pressure drop on the order of hundreds of mTorr at flow rates of hundreds of sccm (standard cubic centimeter). The hollow cathodes of this embodiment enable high pressure hollow cathode array operation in conjunction with a low pressure substrate processing region. In this embodiment, a high pressure side of the hollow cathode, i.e., above the pinch point, is used to create a high pressure hollow cathode. Also, the low pressure side of the hollow cathode, i.e., below the pinch point, can be combined with an electrostatic lens for ion or electron extraction from the hollow cathode plasma.

It should be understood that many different configurations of RF powered electrodes can be implemented within the multi-frequency RF powered hollow cathodes disclosed herein. For example, as disclosed herein with regard to FIGS. 6A-7, hollow cathodes can be assembled in layers of conducting plates separated by dielectric sheets, with arrays of holes formed therethrough. Also, as disclosed in the example of FIGS. 3A-4B, the electrodes of the hollow cathode can be concentrically defined, such that one electrode is present within a hole of another electrode. Also, as shown in the example of FIGS. 4A-4B, the electrodes of the hollow cathode can form annuli for process gas flow.

Additionally, the hollow cathodes can include other shapes not explicitly shown herein, or direct the flow of process gas off-normal from the electrode surface of the hollow cathode. In some embodiments, hollow cathodes can be placed in arrays of unit cells, where electrodes having different frequency combinations are disposed in close proximity to each other. Also, in some embodiments, such as described with regard to FIGS. 3A-3B, different regions of a hollow cathode can be arranged such that an outer region is powered with a first set of RF power frequencies, while an inner region is powered with a second set of RF power frequencies, where the first and second sets of RF power frequencies are different.

While this invention has been described in terms of several embodiments, it will be appreciated that those skilled in the art upon reading the preceding specification and studying the drawings will realize various alterations, additions, permutations and equivalents thereof. The present invention includes all such alterations, additions, permutations, and equivalents as fall within the true spirit and scope of the invention.

What is claimed is:

1. A hollow cathode system for plasma generation in substrate plasma processing, comprising:
an electrically conductive member shaped to circumscribe an interior cavity, wherein the electrically conductive member is formed to have a process gas inlet in fluid communication with the interior cavity, and wherein the electrically conductive member is formed to have an opening that exposes the interior cavity to a substrate processing region;
a first radiofrequency (RF) power source in electrical communication with the electrically conductive member so as to enable transmission of a first RF power to the electrically conductive member; and
a second RF power source in electrical communication with the electrically conductive member so as to enable transmission of a second RF power to the electrically conductive member,
wherein the first and second RF power sources are independently controllable such that the first and second RF powers are independently controllable with regard to frequency and amplitude.

2. A hollow cathode system for plasma generation in substrate plasma processing as recited in claim 1, wherein the electrically conductive member is cylindrically shaped.

3. A hollow cathode system for plasma generation in substrate plasma processing as recited in claim 1, wherein the electrically conductive member is a plate having a hole formed there through, wherein the interior cavity is within the hole of the plate.

4. A hollow cathode system for plasma generation in substrate plasma processing as recited in claim 1, wherein the electrically conductive member is formed in multiple parts, including a central solid cylinder and an outer hollow cylinder, wherein the central solid cylinder and the outer hollow cylinder are sized such that the interior cavity is formed between the central solid cylinder and the outer hollow cylinder.

5. A hollow cathode system for plasma generation in substrate plasma processing as recited in claim 4, wherein the first RF power source is in electrical communication with the central solid cylinder, and wherein the second RF power source is in electrical communication with the outer hollow cylinder.

6. A hollow cathode system for plasma generation in substrate plasma processing as recited in claim 4, wherein both the first and second RF power sources are in electrical communication with each of the central solid cylinder and the outer hollow cylinder.

7. A hollow cathode system for plasma generation in substrate plasma processing as recited in claim 1, wherein the electrically conductive member is formed in multiple parts so as to segment the interior cavity into multiple interior cavities, the electrically conductive member including a central hollow cylinder and an outer hollow cylinder disposed in a concentric and spaced apart manner with respect to each other, wherein a first interior cavity is formed within the central hollow cylinder, and wherein a second interior cavity is formed between the central hollow cylinder and the outer hollow cylinder.

8. A hollow cathode system for plasma generation in substrate plasma processing as recited in claim 7, wherein the first RF power source is in electrical communication with the central hollow cylinder, and wherein the second RF power source is in electrical communication with the outer hollow cylinder.

9. A hollow cathode system for plasma generation in substrate plasma processing as recited in claim 8, wherein a first process gas inlet of the first interior cavity is in fluid communication with a first process gas source, and wherein a second process gas inlet of the second interior cavity is in fluid communication with a second process gas source, wherein the first and second process gas sources are independently controllable with regard to process gas type, process gas pressure, process gas flow rate, process gas temperature, or any combination thereof.

10. A hollow cathode system for plasma generation in substrate plasma processing as recited in claim 7, wherein both the first and second RF power sources are in electrical communication with each of the central hollow cylinder and the outer hollow cylinder.

11. A hollow cathode system for plasma generation in substrate plasma processing as recited in claim 10, wherein process gas inlets of both the first and second interior cavities are in fluid communication with a common process gas source.

12. A hollow cathode system for plasma generation in substrate plasma processing as recited in claim 1, further comprising:
a first electrically grounded member formed to circumscribe the process gas inlet; and
a first dielectric spacer formed to circumscribe the process gas inlet, the first dielectric spacer disposed between the first electrically grounded member and the electrically conductive member.

13. A hollow cathode system for plasma generation in substrate plasma processing as recited in claim 12, further comprising:
a second electrically grounded member formed to circumscribe the opening that exposes the interior cavity to the substrate processing region; and
a second dielectric spacer formed to circumscribe the opening that exposes the interior cavity to the substrate processing region, the second dielectric spacer disposed between the second electrically grounded member and the electrically conductive member.

14. A hollow cathode system for plasma generation in substrate plasma processing as recited in claim 1, further comprising:
a first matching circuit connected between the first RF power source and the electrically conductive member, wherein the first matching circuit is defined to prevent reflection of the first RF power from the electrically conductive member; and
a second matching circuit connected between the second RF power source and the electrically conductive member, wherein the second matching circuit is defined to prevent reflection of the second RF power from the electrically conductive member.

15. A hollow cathode system for plasma generation in substrate plasma processing as recited in claim 1, further comprising:
one or more additional RF power sources in electrical communication with the electrically conductive member so as to enable transmission of additional corresponding RF powers to the electrically conductive member, wherein the additional RF power sources are independently controllable such that the additional RF powers are independently controllable with regard to frequency and amplitude.

16. A hollow cathode system for plasma generation in substrate plasma processing as recited in claim 1, wherein the first RF power source is defined to generate the first RF power having a frequency of either 2 megaHertz (MHz), 27 MHz, 60 MHz, or 400 kiloHertz (kHz), and wherein the second RF power source is defined to generate the second RF power having a frequency of either 2 MHz, 27 MHz, 60 MHz, or 400 kHz, and wherein the frequency of the first RF power is different from the frequency of the second RF power.

17. A method for substrate plasma processing, comprising:
disposing a substrate in exposure to a substrate processing region;
disposing multiple hollow cathodes in exposure to the substrate processing region;
flowing a process gas through the multiple hollow cathodes; and
transmitting a plurality of radiofrequency (RF) powers to the multiple hollow cathodes, wherein the plurality of RF powers are independently controlled with regard to frequency and amplitude and include at least two different frequencies, and wherein at least one of the plurality of RF powers transforms the process gas into a plasma as the process gas flows through the multiple hollow cathodes,
whereby reactive species within the plasma enter the substrate processing region to do work on the substrate.

18. A method for substrate plasma processing as recited in claim 17, further comprising:
controlling a pressure of the process gas, wherein the pressure of the process gas enables formation of the plasma by some of the plurality of RF powers and does not enable formation of the plasma by others of the plurality of RF powers.

19. A method for substrate plasma processing as recited in claim 18, wherein the pressure of the process gas is controlled within a range extending from about 1 milliTorr (mTorr) to about 500 mTorr.

20. A method for substrate plasma processing as recited in claim 17, further comprising:
setting a process gap distance as measured perpendicularly between the substrate and the multiple hollow cathodes within a range extending from about 1 cm to about 10 CM.

21. A method for substrate plasma processing as recited in claim 17, wherein a number of the multiple hollow cathodes is within a range extending from about 25 to about 100.

22. A method for substrate plasma processing as recited in claim 17, wherein the plurality of RF powers include two or more frequencies from the group consisting of 2 megaHertz (MHz), 27 MHz, 60 MHz, and 400 kiloHertz (kHz).

23. A method for substrate plasma processing as recited in claim 17, further comprising:
controlling frequency and amplitude of a first set of one or more RF powers of the plurality of RF powers so as to promote generation of a first type of reactive species within the plasma.

24. A method for substrate plasma processing as recited in claim 23, further comprising:
controlling frequency and amplitude of a second set of one or more RF powers of the plurality of RF powers so as to promote generation of a second type of reactive species within the plasma.

25. A method for substrate plasma processing as recited in claim 24, wherein the first type of reactive species is ions, and wherein the second type of reactive species is radicals, and wherein the frequency of the first set of one or more RF powers is lower than the frequency of the second set of one or more RF powers.
